(19) United States
(12) Patent Application Publication
(10) Pub. No.: US 2009/0140331 A1
(43) Pub. Date: Jun. 4, 2009

(54) METHOD OF FABRICATING HIGH VOLTAGE DEVICE

(76) Inventor: Sun-Kyung Kang, Bucheon-si (KR)

Correspondence Address: SHERR & VAUGHN, PLLC, 620 HERNDON PARKWAY, SUITE 200, HERNDON, VA, 20170, US

(21) Appl. No.: 12/325,156

(22) Filed: Nov. 29, 2008

(30) Foreign Application Priority Data
Dec. 3, 2007 (KR) 10-2007-0124417

(51) Int. Cl. H01L 29/78; H01L 21/336

(52) U.S. Cl. 257/330; 438/270; 257/E29.262; 257/E21.41

(57) ABSTRACT

A method of fabricating a high voltage device by which an area due to isolation between a source and a drain can be reduced by planarizing a gate in forming a symmetric high voltage device having vertical-type drift regions. Accordingly, the gate is formed in a trench at a height lower than an oxide spacer to reduce an area for isolation between source and drain.

The present application claims priority under 35 U.S.C. §119 to Korean Patent Application No. 10-2007-0124417 (filed on Dec. 3, 2007), which is hereby incorporated by reference in its entirety.

### BACKGROUND

A high voltage device requires a lightly doped drift region in a drain to have high voltage resistance. The drift region may occupy the largest portion in size of the high voltage device. As the voltage resistance required by the high voltage device gets higher, the drift region needs to get wider in a horizontal direction. When the high voltage resistance is provided, a length of a channel region should be configured long to prevent “punch-through.” The channel length occupies the second largest portion of the high voltage device.

Referring to FIG. 1, a high voltage device may include a lightly-doped drift region 11 formed in a predetermined area of a p-type semiconductor substrate 10. A gate oxide layer 12 is formed on and/or over the semiconductor substrate 10. A field oxide layer 13 for field plate is formed on and/or over the semiconductor substrate 11 corresponding to a portion of a drift region 11. A gate 14 is formed on and/or over the gate oxide layer 12 and the field plate 13. Source 15 and drain 16, which are heavily doped n-type impurity regions, are formed in the semiconductor substrate 10 adjacent both sides of the gate 14. The source 15 is formed spaced apart form the drift region 11 while the drain 16 is formed within the drift region 11. A channel region 17 is formed in the substrate 10 under the gate 14 between the source 15 and the drift region 11.

Thus, the drift region 11 in such a high voltage device has a horizontal configuration, i.e., is formed having a greater overall width than overall thickness. In order to enhance voltage resistance characteristics, the drift region 11 should be extended in the vertical direction, which is, however, against the demands for the downsizing and ultra-high integration of semiconductor devices.

### SUMMARY

Embodiments relate to a method of fabricating a high voltage device such as a symmetric high voltage device having vertical drift regions, i.e., drift regions formed having a greater overall thickness than overall width.

Embodiments relate to a method of fabricating a high voltage device by which a size of a device is reduced with voltage resistance over a level of a high voltage device and by which a wafer step difference is lowered to minimize the out-of-focus in a patterning step.

Embodiments relate to a method of fabricating a high voltage device that may include at least one of the following: forming a pair of symmetrical vertical-type drift regions spaced apart in a semiconductor substrate, forming an oxide layer in the semiconductor substrate and overlapping the drift regions, forming a trench in the semiconductor substrate between the drift regions, forming an oxide spacer on sidewalls of the trench, forming a gate in the trench and over the oxide layer, planarizing the gate, and forming a source and a drain in the drift regions, respectively.

Embodiments relate to a method that may include at least one of the following: forming a pair of vertical-type drift regions spaced apart in a semiconductor substrate; and then forming an oxide layer in the semiconductor substrate and overlapping a portion of the drift regions; and then forming a trench in the semiconductor substrate between the drift regions; and then forming an oxide spacer on sidewalls of the trench; and then forming a gate in the trench and on the oxide layer; and then planarizing the gate; and then forming a source and a drain in the drift regions, respectively.

Embodiments relate to a device that may include at least one of the following: a pair of vertical-type drift regions formed spaced apart in a semiconductor substrate; a trench formed in the semiconductor substrate including the drift regions; insulating layer patterns formed at the uppermost portion of the trench and in the drift regions, respectively; a spacer formed on sidewalls of the trench and exposed sidewalls of the insulating layer patterns; a gate formed in the trench; and a source and a drain formed in the drift regions, respectively.

Embodiments relate to a device that may include at least one of the following: a first drift region formed in a semiconductor substrate; a second drift region formed spaced apart from the first drift region in the semiconductor substrate; a trench formed in the semiconductor substrate and the drift regions between the drift regions; a first insulating layer pattern formed at the uppermost portion of the trench in the first drift region; a second insulating layer pattern formed at the uppermost portion of the trench in the second drift region; a first spacer formed on a sidewall of the trench in the first drift region and over the sidewall of the first insulating layer pattern; a second spacer formed on a sidewall of the trench in the second drift region and over the sidewall of the second insulating layer pattern; a gate formed in the trench and contacting the first and second spacers; a source formed in the first drift region; and a drain formed in the second drift region. In accordance with embodiments, an uppermost surface of the gate is formed below the uppermost surface of the spacer.

In accordance with embodiments, the gate is etched by CMP (Chemical Mechanical Polishing) and is etched to have a thickness smaller than that of the oxide spacer. In accordance with embodiments, by configuring symmetric vertical-type drift regions, the lengths of drift and channel regions can be smaller than those of the related art. Therefore, a size of a high voltage device can be reduced. Secondly, in forming a gate electrode, a gate is formed lower than an oxide spacer in a trench area by etch to reduce an area for isolation between source and drain. And, a step difference of wafer is lowered to prevent the out-of-focus in a patterning step.

### DRAWINGS

FIG. 1 is a cross-sectional diagram of a high voltage device.

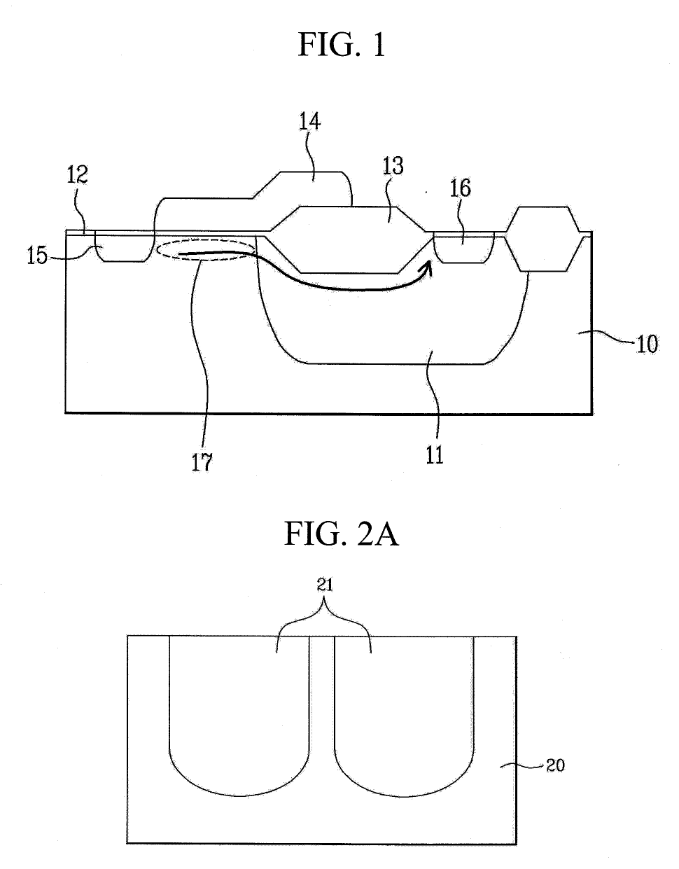

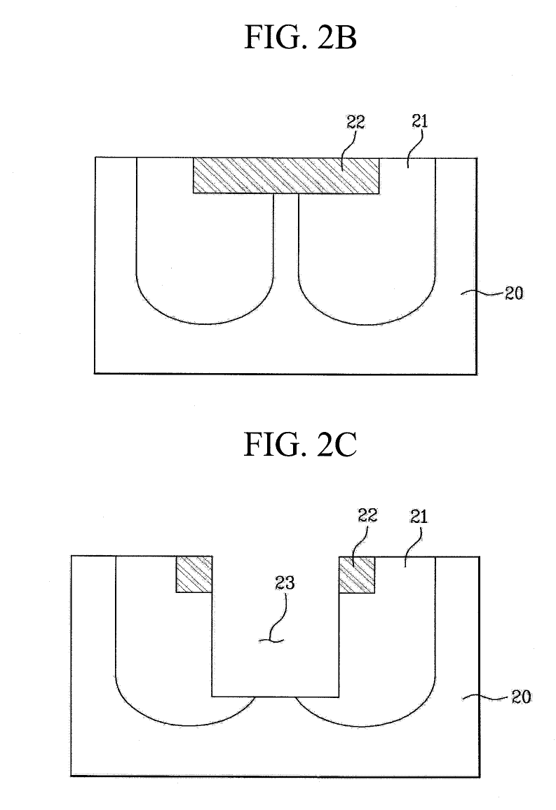

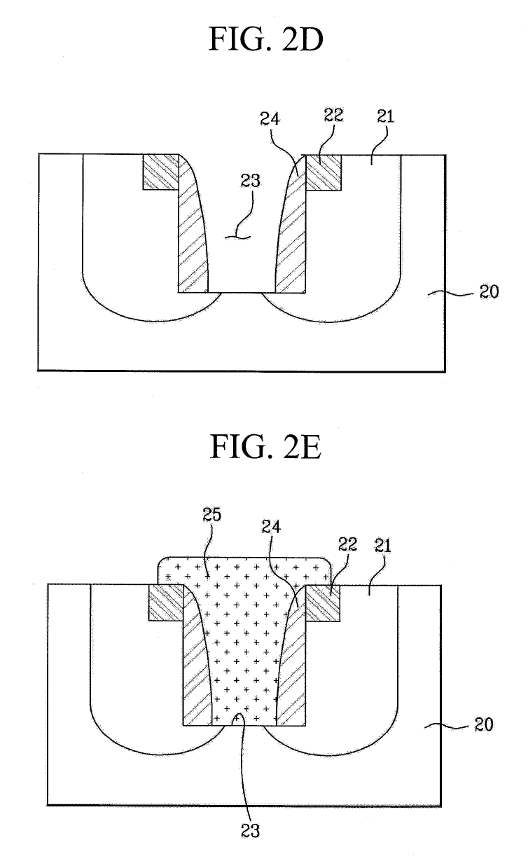

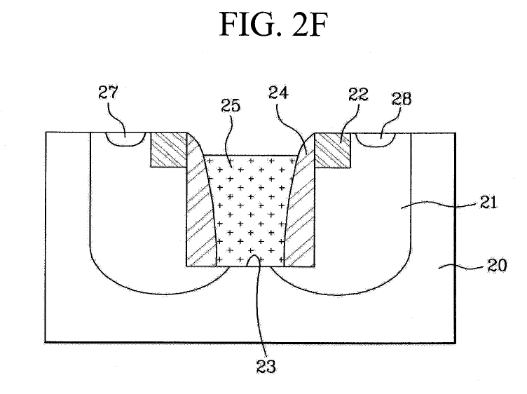

Example FIGS. 2A to 2F illustrate a method of fabricating a high voltage device in accordance with embodiments.

### DESCRIPTION

Example FIGS. 2A to 2F are cross-sectional diagrams for a method of fabricating a high voltage device in accordance with embodiments. Referring to example FIG. 2A, a pair of drift regions 21 are formed symmetric in a p-type semiconductor substrate 20. The drift regions 21 are formed spaced apart from each other a predetermined distance. In particular, the drift regions 21 are formed in a manner of forming a drift region mask pattern on and/or over the semiconductor substrate 20, performing n-type impurity ion implantation lightly, and then performing “drive-in” on the implanted impurity ions.

Referring to example FIG. 2B, an oxide layer 22 is formed in the surface of the semiconductor substrate 20. The oxide layer 22 is formed across and overlap a portion of both of the drift regions 21. The overall width of the oxide layer 22 is greater than the predetermined distance between the drift regions 21. The oxide layer 22 is formed by forming an oxide layer mask pattern on and/or over the semiconductor substrate 20. The semiconductor substrate 20 and the drift regions 21 are then etched to a prescribed depth. The oxide layer 22 is deposited in the etched portion of the drift regions 21 and the semiconductor substrate 20 and then planarized.

Referring to example FIG. 2C, a trench 23 is formed in the semiconductor substrate 20 including the drift regions 21. The trench 23 is formed having a depth smaller than the thickness (depth profile) of each of the drift regions 21 and a width smaller than the width of the oxide layer 22. The trench 23 is formed in a manner of forming a trench mask pattern and then etching the semiconductor substrate 20 including the drift regions 21 and oxide layer 22 to a prescribed depth. Accordingly, oxide layer patterns 22 are formed in a respective drift region 21.

Referring to example FIG. 2D, an oxide spacer 24 is formed on sidewalls of the trench 23 and contacting sidewalls of a respective oxide layer pattern 22 and drift region 22. The oxide spacer 24 is used as a field plate of a high voltage device. The oxide spacer 24 is formed in a manner of depositing an oxide layer on and/or over the semiconductor substrate 20 and then etching the deposited oxide layer by anisotropic dry etching.

Referring to example FIG. 2E, a gate 25 is then formed in the trench 23 and on a portion of the uppermost surface of each oxide layer pattern 22. The gate 25 is formed by depositing a gate conductive layer to fill the trench 23. After a gate mask pattern has been formed, the gate conductive layer is etched. In particular, the gate conductive layer projected over the silicon substrate 20 is planarized by CMP (Chemical Mechanical Polishing).

Referring to example FIG. 2F, the gate conductive layer is etched to have a height less than that of the oxide spacer 24. Therefore, an area for isolation between the gate conductive layer and source/drain is reduced to minimize an area occupied by the device. And, a step difference of wafer is lowered by etching the gate by CMP to prevent the out-of-focus in a next patterning step. A source 27 and a drain 28 is formed in a respective one of the drift regions 21 spaced from a respective oxide layer pattern 22.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a pair of vertical-type drift regions spaced apart in a semiconductor substrate; and then
forming an oxide layer in the semiconductor substrate and overlapping a portion of the drift regions; and then
forming a trench in the semiconductor substrate between the drift regions; and then
forming an oxide spacer on sidewalls of the trench; and then
forming a gate in the trench and on the oxide layer;
planarizing the gate; and then
forming a source and a drain in the drift regions, respectively.

2. The method of claim 1, wherein the gate is etched by chemical mechanical polishing.

3. The method of claim 1, wherein the gate is etched to have a height smaller than that of the oxide spacer.

4. The method of claim 1, wherein the trench is formed to have a width less than the width of the oxide layer.

5. The method of claim 1, wherein the oxide layer is formed to have a width greater than the space between the drift regions.

6. The method of claim 1, wherein the trench is formed having a depth less than that of the drift regions.

7. The method of claim 1, wherein the oxide spacer comprises a field plate for a high voltage device.

8. The method of claim 1, wherein the oxide spacer is formed by an anisotropic dry etch.

9. A device comprising:
a pair of vertical-type drift regions formed spaced apart in a semiconductor substrate;
a trench formed in the semiconductor substrate including the drift regions;
insulating layer patterns formed at the uppermost portion of the trench and in the drift regions, respectively;
a spacer formed on sidewalls of the trench and exposed sidewalls of the insulating layer patterns;
a gate formed in the trench;
a source and a drain formed in the drift regions, respectively.

10. The device of claim 9, wherein the gate has a height smaller than that of the spacer.

11. The device of claim 9, wherein the insulating layer pattern is formed in the drift regions spaced apart from a respective one of the source and the drain.

12. The device of claim 9, wherein the trench has a depth smaller than that of the drift regions.

13. The device of claim 9, wherein the insulating layer patterns are composed of an oxide.

14. The device of claim 9, wherein the spacer is composed of an oxide.

15. The device of claim 9, wherein the uppermost surface of the insulating layer patterns is coplanar with the uppermost surface of the drift regions, the semiconductor substrate and the source and the drain.

16. A device comprising:
a first drift region formed in a semiconductor substrate;
a second drift region formed spaced apart from the first drift region in the semiconductor substrate;
a trench formed in the semiconductor substrate and the drift regions between the drift regions;
a first insulating layer pattern formed at the uppermost portion of the trench in the first drift region;
a second insulating layer pattern formed at the uppermost portion of the trench in the second drift region;
a first spacer formed on a sidewall of the trench in the first drift region and over the sidewall of the first insulating layer pattern;
a second spacer formed on a sidewall of the trench in the second drift region and over the sidewall of the second insulating layer pattern;
a gate formed in the trench and contacting the first and second spacers;
a source formed in the first drift region; and
a drain formed in the second drift region,
wherein an uppermost surface of the gate is formed below the uppermost surface of the spacer.

17. The device of claim 16, wherein the first and second drift regions comprise vertical-type drift regions.

18. The device of claim 6, wherein the trench has a depth less than the depth of the first and second drift regions.

19. The device of claim 16, wherein the first and second insulating layer patterns are composed of an oxide.

20. The device of claim 16, wherein the first and second spacers are composed of an oxide.
